(19) United States
(12) Patent Application Publication
(10) Pub. No.: US 2007/0023927 A1
(43) Pub. Date: Feb. 1, 2007

(54) Semiconductor device

(75) Inventors: Noriyuki Nagai, Nara (JP); Tsuyoshi Hamatani, Shiga (JP); Tadaaki Mimura, Osaka (JP)

Correspondence Address: STEPTOE & JOHNSON LLP, 1330 CONNECTICUT AVE., NW, WASHINGTON, DC, 20036, US

(73) Assignee: Matsushita Electric Industrial Co., Ltd., Kadoma-shi (JP)

(21) Appl. No.: 11/487,329

(22) Filed: Jul. 17, 2006

(30) Foreign Application Priority Data
Jul. 26, 2005 (JP) 2005-215166
Mar. 24, 2006 (JP) 2006-081823

(51) Int. Cl. H01L 23/48

(52) U.S. Cl. 257/780

(57) ABSTRACT

When an interlayer film (22) is formed to have a large thickness and an electrode pad (11) is partly or wholly led out from an active region (16), an I/O region (15) can be reduced in area. Thus, it is possible to reduce an area of a semiconductor device.

### BACKGROUND OF THE INVENTION

1. Field of the Invention

The present invention relates to a semiconductor device including an I/O cell for shielding an electrode pad with a wire.

2. Description of the Related Art

Description will be given of a structure of an electrode pad in a conventional semiconductor device with reference to FIGS. 8 to 13.

FIG. 8 is an enlarged view mainly illustrating a portion near an electrode pad in a conventional semiconductor device. Herein, a SiN insulating film and a protection film formed on a surface of the semiconductor device are not illustrated. FIG. 9 is a sectional view illustrating the portion near the electrode pad in the conventional semiconductor device, taken along a line A-A′ in FIG. 8. FIG. 10 is a sectional view illustrating a configuration of the electrode pad formed with a bump in the conventional semiconductor device. FIG. 11 is a plan view illustrating the configuration of the electrode pad formed with the bump in the conventional semiconductor device. FIG. 12 is a sectional view illustrating a configuration of an electrode pad using a conventional rewiring technique. FIG. 13 is a sectional view illustrating a configuration of the electrode pad formed with a bump using the conventional rewiring technique.

As illustrated in FIGS. 8 to 11, the semiconductor device described herein is formed by plural layered Cu wires. An Al electrode pad 11 is formed on an I/O region 15 serving as a circuit region of an I/O cell. When the electrode pad 11 as an external terminal is connected to an external device by means of a bonding wire, the semiconductor device is electrically connected to the external device. The electrode pad 11 is connected to an internal wire (not illustrated) through a pad metal 12. The pad metal 12 has a shape almost equal to that of the electrode pad 11 and is formed by a Cu wire at an uppermost layer in order to lead out the electrode pad 11 from the internal wire. A connection via 13 electrically connects between the electrode pad 11 and the pad metal 12 and is made of Al equal to a material for the electrode pad 11. A diameter 17 of a junction between wire bonding or a stud bump 31 formed on the electrode pad 11 and the electrode pad 11 is smaller than the connection via 13. Further, a junction face is formed on the connection via 13 so as to not protrude therefrom. In order to lessen influence of electrical interference such as noise on the I/O cell formed on the I/O region 15, a shield wire 14 formed by a Cu wire at an uppermost layer is provided near an interface between an active region 16 serving as a functional element formation region of the semiconductor device and the I/O region 15. Further, an interlayer film 22 such as a SiN insulating film and a protection film 23 for protecting the semiconductor device are formed on a whole surface of the semiconductor device except the electrode pad 11. In general, a polyimide film or a PBO film is used as the protection film 23.

In a case where a bump electrode or the like is formed on the semiconductor device, as illustrated in FIG. 12, a flat wiring region is formed by leading out a wire 91 from the electrode pad 11 onto the protection film 23 using a rewiring technique. Then, as illustrated in FIG. 13, a bump, plating, a solder ball 101 or the like is formed on the wiring region.

However, although there is demanded for reduction in chip size of the semiconductor device recently, in this conventional electrode pad structure, an area of the electrode pad must be equal to or more than a specific value for connection of a bonding wire. Since an area of the I/O region cannot be made smaller than the area of the electrode pad, the chip size cannot be reduced, resulting in a problem.

In the conventional rewiring technique, a wire is led out after formation of a semiconductor device; therefore, the wire must be led out to a protection layer having a considerably large thickness for protection of the semiconductor device. Consequently, the conventional rewiring technique has the following problems. An electrical characteristic deteriorates due to a distance of a wire to be led out. Further, the wire deteriorates in its reliability due to a step of the led wire; therefore, it is difficult to move an electrode pad to an active region or the like by the rewiring technique.

### SUMMARY OF THE INVENTION

The present invention is made to solve the aforementioned problems, and it is therefore an object of the present invention to provide a semiconductor device capable of reducing an area thereof by reducing an area of an I/O region.

In order to achieve this object, according to the present invention, a semiconductor device includes an I/O region serving as a circuit region for an I/O cell and an active region serving as a functional element formation region. The semiconductor device comprises a pad metal formed on the I/O region and leading out an internal wire, an interlayer film formed on a whole surface of the semiconductor device with the pad metal being partly exposed therefrom, an electrode pad partly or wholly formed on the interlayer film of the active region, a connection via for electrically connecting between the pad metal and the electrode pad, and a protection film formed on the whole surface of the semiconductor device with the electrode pad being exposed therefrom. Herein, the I/O region is smaller than the electrode pad.

Further, the interlayer film is a SiN film.

Further, the interlayer film has a thickness in a range from 250 to 700 nm.

Further, the interlayer film has a thickness of 300 nm.

Further, the wire and the pad metal are made of Cu and the electrode pad and the connection via are made of Al, respectively.

Further, at least a part of a wire at an uppermost layer located immediately under the electrode pad is a shield wire for shielding the I/O cell.

Further, the electrode pad is connected to an external device through wire bonding.

Further, a stud bump is formed on the electrode pad.

Still further, a diameter of a junction between the electrode pad and the wire bonding is larger than a length of any one of sides of a connection face between the connection via and the electrode pad.

Still further, a diameter of a junction between the electrode pad and the stud bump is larger than a length of any one of sides of a connection face between the connection via and the electrode pad.

Still further, a positional relation between the junction and the connection via deviates in a direction parallel with any one of sides of the electrode pad.

### BRIEF DESCRIPTION OF THE DRAWINGS

FIG. 1 is an enlarged view mainly illustrating a portion near an electrode pad in a semiconductor device according to a first embodiment;

FIG. 2 is a sectional view illustrating the portion near the electrode pad in the semiconductor device according to the first embodiment;

FIG. 3 is a sectional view illustrating a configuration of the electrode pad formed with a bump in the first embodiment;

FIG. 4 is a plan view illustrating the configuration of the electrode pad formed with the bump according to the first embodiment;

FIG. 5 is an enlarged view mainly illustrating a portion near an electrode pad in a semiconductor device according to a second embodiment;

FIG. 6 is a sectional view illustrating the portion near the electrode pad in the semiconductor device according to the second embodiment;

FIG. 7 is a sectional view illustrating a configuration of the electrode pad formed with a bump according to the second embodiment;

FIG. 8 is an enlarged view mainly illustrating a portion near an electrode pad in a conventional semiconductor device;

FIG. 9 is a sectional view illustrating the portion near the electrode pad in the conventional semiconductor device;

FIG. 10 is a sectional view illustrating a configuration of the electrode pad formed with a bump in the conventional semiconductor device;

FIG. 11 is a plan view illustrating the configuration of the electrode pad formed with the bump in the conventional semiconductor device;

FIG. 12 is a sectional view illustrating a configuration of the electrode pad using a conventional rewiring technique; and

FIG. 13 is a sectional view illustrating a configuration of the electrode pad formed with a bump using the conventional rewiring technique.

### DESCRIPTION OF THE PREFERRED EMBODIMENTS

Hereinafter, description will be given of preferred embodiments of the present invention with reference to the drawings.

(First Embodiment)

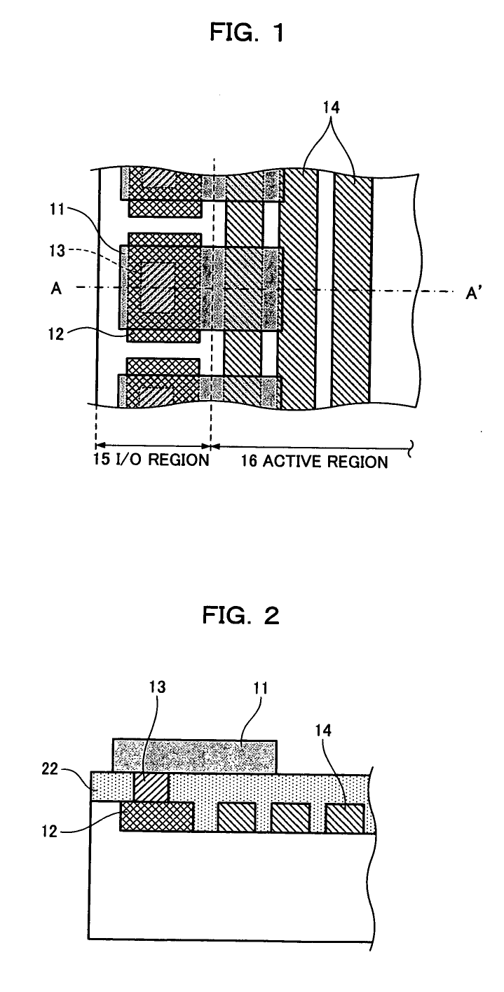

First, description will be given of a semiconductor device according to a first embodiment with reference to FIGS. 1 to 4.

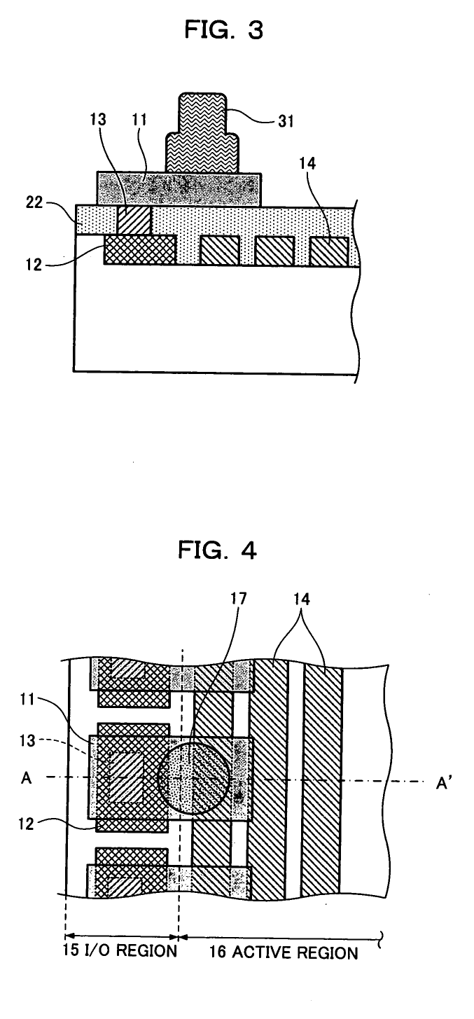

FIG. 1 is an enlarged view mainly illustrating a portion near an electrode pad in the semiconductor device according to first embodiment. FIG. 2 is a sectional view illustrating the portion near the electrode pad in the semiconductor device according to the first embodiment, taken along a line A-A′ in FIG. 1. FIG. 3 is a sectional view illustrating a configuration of the electrode pad formed with a bump in the first embodiment. FIG. 4 is plan view illustrating the configuration of the electrode pad formed with the bump in the first embodiment.

As illustrated in FIGS. 1 and 2, similar to a conventional semiconductor device, an I/O region 15 has a pad metal 12 formed thereon, and the pad metal 12 is formed by a Cu wire at an uppermost layer for leading out an internal wire. A shield wire 14 for lessening influence of electrical interference such as noise on an I/O cell including the I/O cell region 15 and an electrode pad 11 is formed near an interface between an active region 16 and the I/O region 15. The electrode pad 11 in the semiconductor device according to the present invention is led out from the pad metal 12 onto an interlayer film 22 such as a SiN insulating film formed on the shield wire 14 of the active region 16, by means of a conductive layer such as an Al wire, through a connection via 13. The electrode pad 11 is at least partly formed on the active region 16. The semiconductor device is wholly covered with a protection film 23 such as a polyimide film or a PBO film in a state that the electrode pad 11 is exposed therefrom.

A conventional interlayer film has a thickness of about 200 nm. However, in the present invention, the electrode pad 11 is formed without provision of the protection film 23; therefore, the interlayer film 22 must have a thickness of about 300 nm or more in order to improve an anti-cracking property upon wire bonding and the like. When the thickness is about 650 nm, it is possible to secure a considerable anti-cracking property. When the thickness is within a range from 250 to 700 nm, it is possible to almost lessen influence due to a wiring step for lead-out while keeping an anti-cracking property without provision of a pad metal under a bonding region.

As described above, the electrode pad 11 is led out from the pad metal 12 and, then, is formed on the active region 16, so that the pad metal 12 may not have a shape equal to that of the electrode pad 11. Thus, it is possible to reduce an area of the pad metal 12 and to reduce an area of the I/O region 15 to a level capable of forming a circuit for protecting the semiconductor device from a surge. More specifically, it is possible to reduce the area of the I/O region 15 that has been restricted to the area of the electrode pad 11 heretofore, to thereby reduce an area of the semiconductor device.

As illustrated in FIGS. 3 and 4, a stud bump 31 may be formed as an external terminal on the electrode pad 11.

According to a conventional technique, in order to keep flatness at a junction position of wire bonding or a stud bump, the junction position of the wire bonding or the stud bump must be located on a connection via and the connection via must be larger than a diameter of a junction. According to the present invention, wire bonding or the stud bump 31 is connected onto the electrode pad 11 thus led out; therefore, the degree of freedom in shape, size and position of the connection via 13 increases. In addition, the connection via 13 can be made smaller than a diameter 17 of a junction between the wire bonding or the stud bump 31 formed on the electrode pad 11 and the electrode pad 11. Moreover, the diameter 17 is larger than a length in a direction parallel with any one of sides of a section of the connection via 13 and, further, the junction can be formed outside the connection via 13. As described above, the connection via 13 can be made small and, also, the area of the I/O region 15 can be reduced; thus, the area of the semiconductor device can be reduced. In addition, since the bonding junction face is not overlapped with the connection via 13, a damage to a lower portion due to bonding to a step can be reduced.

(Second Embodiment)

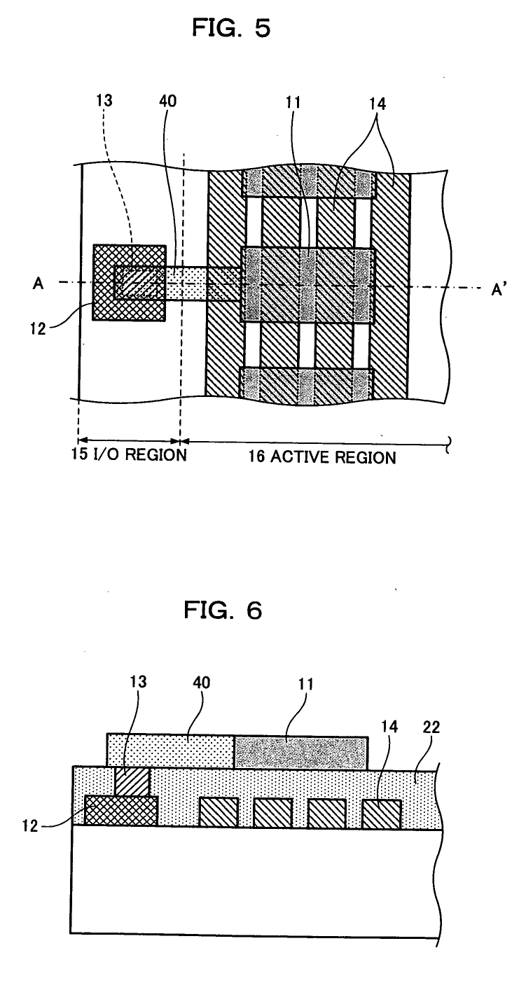

Next, description will be given of a semiconductor device according to a second embodiment with reference to FIGS. 5 to 7.

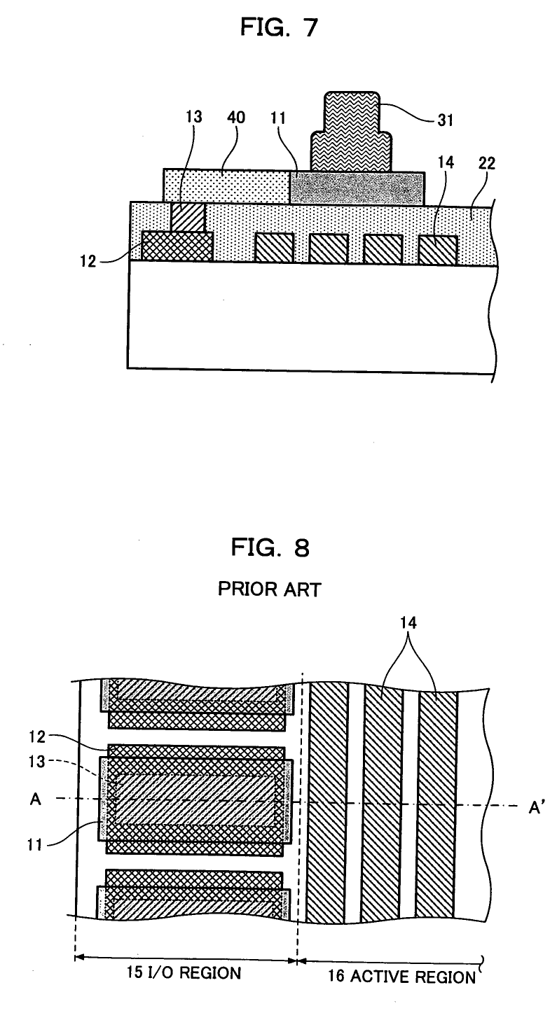

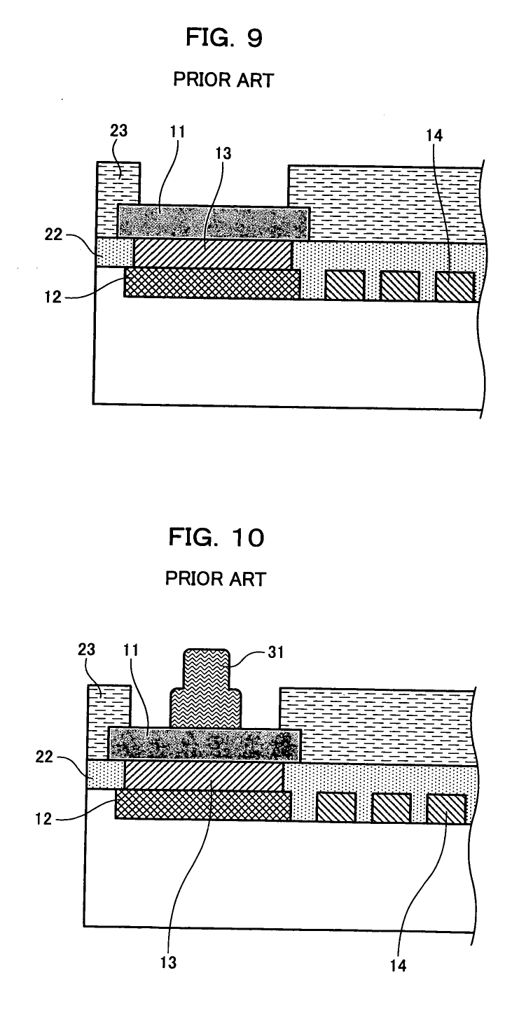

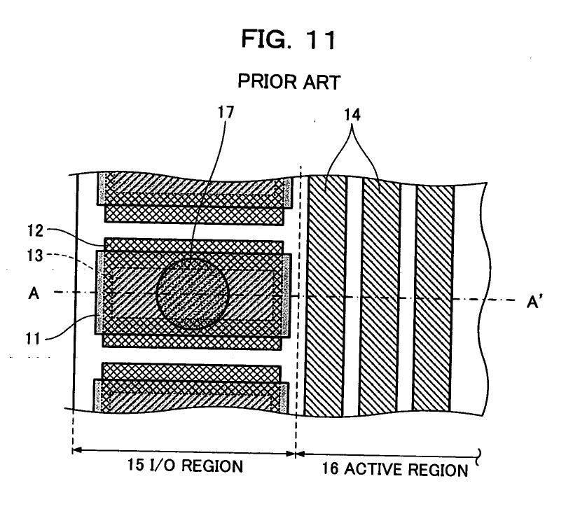

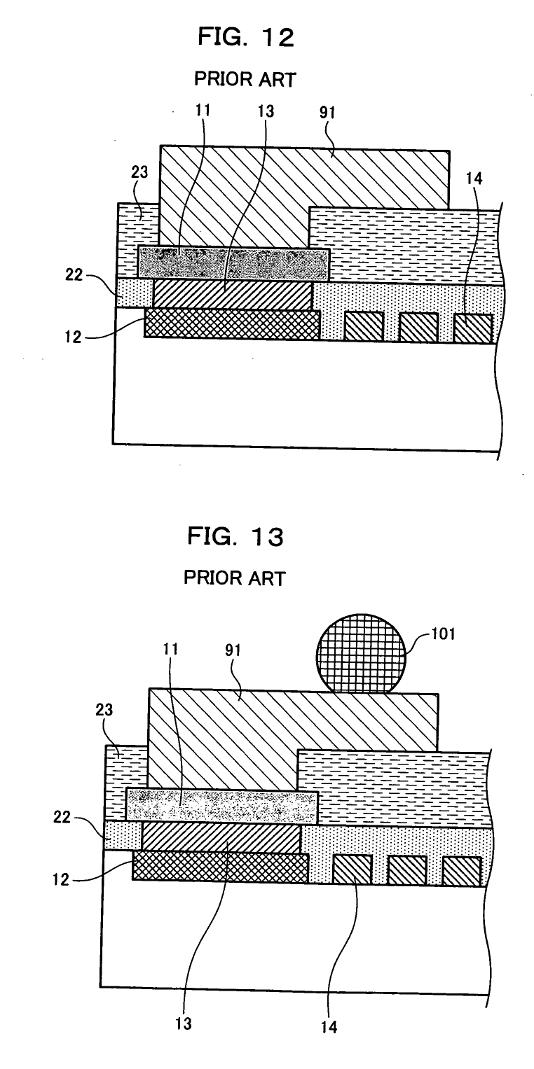

FIG. 5 is an enlarged view mainly illustrating a portion near an electrode pad in the semiconductor device according to the second embodiment. FIG. 6 is a sectional view illustrating the portion near the electrode pad in the semiconductor device according to the second embodiment, taken along a line A-A′ in FIG. 5. FIG. 7 is a sectional view illustrating a configuration of an electrode pad formed with a bump in the second embodiment.

In the first embodiment, the electrode pad is formed across the I/O region and the active region. In the second embodiment, as illustrated in FIGS. 5 and 6, an electrode pad 11 is led out from an I/O region 15 to an active region 16 by means of a wire 40.

As described above, the electrode pad 11 is led out from a pad metal 12 and, then, is formed on the active region 16, so that the pad metal 12 is not necessarily to have a shape equal to that of the electrode pad 11. Thus, it is possible to reduce an area of the pad metal 12 and to reduce an area of the I/O region 15 to a level capable of forming a circuit for protecting the semiconductor device from a surge. More specifically, it is possible to reduce the area of the I/O region 15 that has been restricted to the area of the electrode pad 11 here to fore, to thereby reduce an area of the semiconductor device.

As illustrated in FIG. 7, a semiconductor chip having the aforementioned pad structure is not subjected to plating and is not formed with a bump using a rewiring technique, but an electrode pad can be connected to an external terminal using wire boding, a stud bump 31 or the like.

The aforementioned first and second embodiments describe a case of using a Cu wire and an Al wire as wiring layers; however, materials for the wires are optional. In addition, the aforementioned first and second embodiments describe a case that only a shield wire is formed as a wiring layer located immediately under an electrode pad, with reference to the drawings. However, the shield wire may be replaced with a signal wire, a power supply wire or the like as long as a shield effect for an electrode pad can be maintained.

What is claimed is:

1. A semiconductor device including an I/O region serving as a circuit region for an I/O cell and an active region serving as a functional element formation region, the semiconductor device comprising:
a pad metal formed on the I/O region and leading out an internal wire;
an interlayer film formed on a whole surface of the semiconductor device with the pad metal being partly exposed therefrom;
an electrode pad partly or wholly formed on the interlayer film of the active region;
a connection via for electrically connecting between the pad metal and the electrode pad; and
a protection film formed on the whole surface of the semiconductor device with the electrode pad being exposed therefrom, wherein
the I/O region is smaller than the electrode pad.

2. The semiconductor device according to claim 1, wherein the interlayer film is a SiN film.

3. The semiconductor device according to claim 2, wherein the interlayer film has a thickness in a range from 250 to 700 nm.

4. The semiconductor device according to claim 2, wherein the interlayer film has a thickness of 300 nm.

5. The semiconductor device according to claim 1, wherein the wire and the pad metal are made of Cu and the electrode pad and the connection via are made of Al, respectively.

6. The semiconductor device according to claim 2, wherein the wire and the pad metal are made of Cu and the electrode pad and the connection via are made of Al, respectively.

7. The semiconductor device according to claim 1, wherein at least a part of a wire at an uppermost layer located immediately under the electrode pad is a shield wire for shielding the I/O cell.

8. The semiconductor device according to claim 1, wherein the electrode pad is connected to an external device through wire bonding.

9. The semiconductor device according to claim 1, wherein a stud bump is formed on the electrode pad.

10. The semiconductor device according to claim 8, wherein a diameter of a junction between the electrode pad and the wire bonding is larger than a length of any one of sides of a connection face between the connection via and the electrode pad.

11. The semiconductor device according to claim 9, wherein a diameter of a junction between the electrode pad and the stud bump is larger than a length of any one of sides of a connection face between the connection via and the electrode pad.

12. The semiconductor device according to claim 10, wherein
a positional relation between the junction and the connection via deviates in a direction parallel with any one of sides of the electrode pad.

13. The semiconductor device according to claim 11, wherein a positional relation between the junction and the connection via deviates in a direction parallel with any one of sides of the electrode pad.
